(19) United States
(12) Patent Application Publication
(10) Pub. No.: US 2026/0269187 A1
(43) Pub. Date: Sep. 10, 2026

(54) REACTION CHAMBER AND WAFER ETCHING DEVICE

(71) Applicant: Beijing E-Town Semiconductor Technology Co., Ltd., Beijing (CN)

(72) Inventors: Changle GUAN, Beijing (CN); Xinyun ZHANG, Beijing (CN); Qiang FAN, Beijing (CN)

(21) Appl. No.: 19/135,245

(22) PCT Filed: Nov. 9, 2023
(86) PCT No.: PCT/CN2023/130651

§ 371 Date: Jun. 3, 2025

(30) Foreign Application Priority Data
Dec. 25, 2022 (CN) 202211669615.4

(51) Int. Cl. H01J 37/32; F16K 1/12; F16K 1/46; H10P 72/00

(52) U.S. Cl. CPC H01J 37/3244; F16K 1/12; F16K 1/465; H01J 37/32513; H10P 72/0421; H01J 2237/334

(57) ABSTRACT

Provided is a reaction chamber and a wafer etching device. The reaction chamber includes a chamber body, a first support part and a pumping part. The chamber body includes a top plate and a bottom plate. The top plate is provided with an inlet port, the bottom plate is provided with a pumping port, a wafer stage is provided between the inlet port and the pumping port, and a pumping region is formed between an inner wall of the chamber body and the wafer stage. The first support part is disposed between the inner wall of the chamber body and the wafer stage. The pumping part includes a valve plate and a valve core. The valve plate is disposed inside the chamber body and connected to a first end of the valve core, and a second end of the valve core is liftably inserted into the pumping port.

### TECHNICAL FIELD

The present disclosure relates to the technical field of semiconductors, and particularly relates to a reaction chamber and a wafer etching device.

### BACKGROUND

In a wafer etching process, a reaction chamber of a wafer etching device is mainly used for accommodating a wafer and enabling an etching process on the wafer in the reaction chamber. Whether the structural design of the reaction chamber is reasonable may directly influence the etching effect of the wafer.

### SUMMARY

According to a first aspect of the embodiments of the present disclosure, there is provided a reaction chamber applied to a wafer etching device, including: a chamber body including a top plate and a bottom plate disposed oppositely in a vertical direction, wherein the top plate is provided with an inlet port, the bottom plate is provided with a pumping port, a wafer stage is provided between the inlet port and the pumping port, and a pumping region is formed between an inner wall of the chamber body and the wafer stage; a first support part disposed between the inner wall of the chamber body and the wafer stage; and a pumping part including a valve plate and a valve core, wherein the valve plate is disposed inside the chamber body and connected to a first end of the valve core, a second end of the valve core is liftably inserted into the pumping port, and when the valve core is in a first working position, a first annulus is formed between the valve plate and the bottom plate, and a second annulus is formed between the valve core and the pumping port; wherein the first annulus, the second annulus, and the pumping region are disposed coaxially.

According to a second aspect of the embodiments of the present disclosure, there is provided a wafer etching device, including: the reaction chamber provided in the first aspect of the embodiments of the present disclosure.

It should be understood that the description in this summary is not intended to limit the critical or essential features of the embodiments of the present disclosure, nor are they intended to limit the scope of the present disclosure. Other features of the present disclosure will become apparent from the following description.

### BRIEF DESCRIPTION OF THE DRAWINGS

The above and other features, advantages, and aspects of various embodiments of the present disclosure will become more apparent by referring to the following detailed description in conjunction with the accompanying drawings. In the drawings, the same or similar reference signs refer to the same or similar elements.

FIG. 1a is a schematic structural diagram of a reaction chamber according to an embodiment of the present disclosure.

FIG. 1b is another schematic structural diagram of a reaction chamber according to an embodiment of the present disclosure.

FIG. 2 is a schematic internal perspective view of a reaction chamber according to an embodiment of the present disclosure.

FIG. 3 is a schematic top view of a wafer stage in a reaction chamber according to an embodiment of the present disclosure.

FIG. 4 is a schematic top view of a wafer stage in a reaction chamber according to an embodiment of the present disclosure.

FIG. 5 is a schematic structural diagram of a reaction chamber according to an embodiment of the present disclosure.

FIG. 6 is a schematic structural diagram of a reaction chamber according to an embodiment of the present disclosure.

### DETAILED DESCRIPTION

Exemplary embodiments of the present disclosure will be described below in conjunction with the accompanying drawings, in which various details of the embodiments of the present disclosure are included to assist understanding, and should be considered as being merely exemplary. Therefore, those of ordinary skill in the art will recognize that various changes and modifications of the embodiments described herein can be made without departing from the scope and spirit of the present disclosure. Also, descriptions of well-known functions and constructions are omitted in the following description for clarity and conciseness.

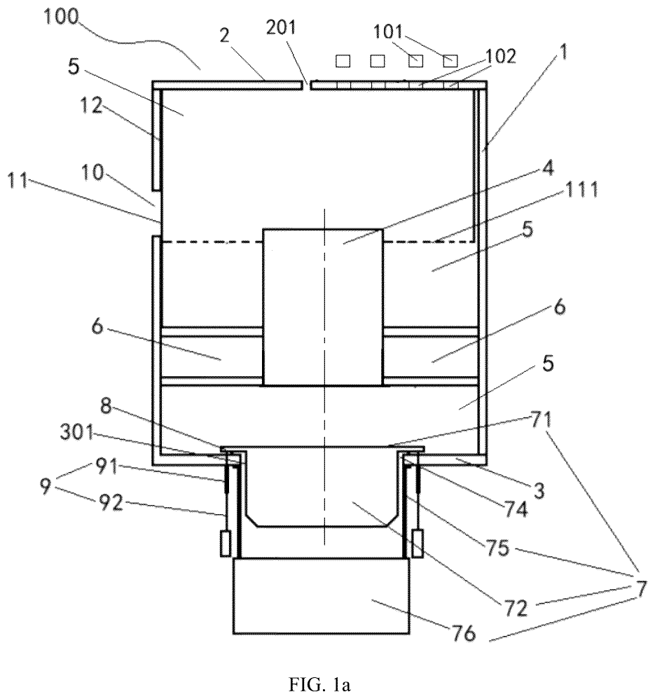

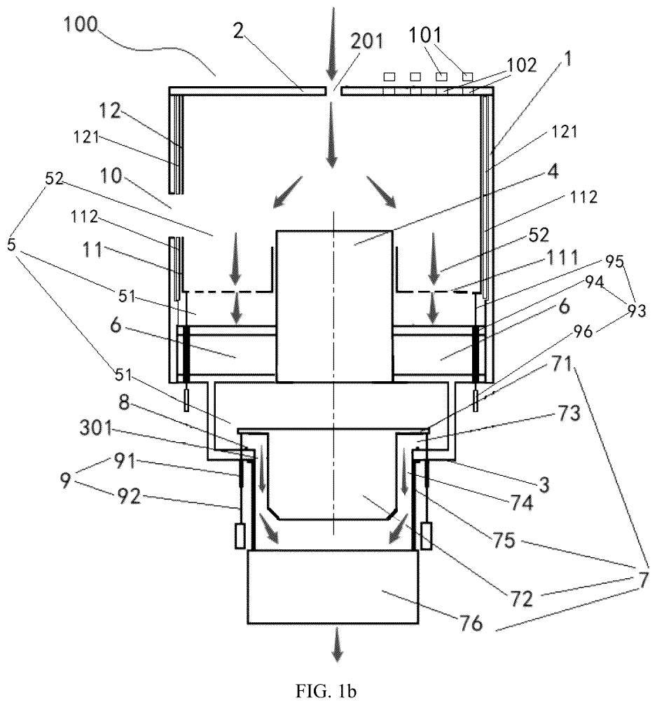

As shown in FIGS. 1a to 5, an embodiment the present disclosure provides a reaction chamber 100 applied to a wafer etching device, including a chamber body 1, a first support part 61, and a pumping part 7.

The chamber body 1 includes a top plate 2 and a bottom plate 3 disposed oppositely in a vertical direction. The top plate 2 is provided with an inlet port 201. The bottom plate 3 is provided with a pumping port 301. A wafer stage 4 is provided between the inlet port 201 and the pumping port 301. A pumping region 5 is formed between the inner wall of the chamber body 1 and the wafer stage 4.

The first support part 61 is disposed between the inner wall of the chamber body 1 and the wafer stage 4.

The pumping part 7 includes a valve plate 71 and a valve core 72. The valve plate 71 is disposed inside the chamber body 1 and connected to a first end of the valve core 72. A second end of the valve core 72 is liftably inserted into the pumping port 301. A second annulus 74 is formed between the valve core 72 and the pumping port 301. When the valve core 72 is in a first working position (as shown in FIGS. 1a and 1b), a first annulus 73 is formed between the valve plate 71 and the bottom plate 3.

The first annulus 73, the second annulus 74, and the pumping region 5 are disposed coaxially.

According to the embodiment of the present disclosure, the gas in a space around the wafer stage can be pumped into the pumping port through a uniform gas flow field, thereby ensuring the uniformity in the wafer etching process results.

According to the embodiments of the present disclosure, it should be noted that: the horizontal direction in the embodiments of the present disclosure is defined as a direction from left to right of the reaction chamber 100 in FIGS. 1a and 1b; and the vertical direction is defined as a direction from top to bottom of the reaction chamber 100 in FIGS. 1a and 1b.

The inlet port 201 may be connected to a gas inlet pipeline, and a process gas in the gas inlet pipeline is delivered into the chamber body 1 through the inlet port 201. The shape and number of inlet ports 201 may be selected and adjusted as needed, and are not specifically limited here. The position of the inlet port 201 in the top plate 2 may be selected and adjusted as needed. For example, the inlet port 201 is provided in the top plate 2 at a position opposite to the wafer, or the inlet port 201 may be provided at any position on the top plate 2.

The pumping port 301 is configured to pump out the process gas inside the chamber body 1. The shape and caliber of the pumping port 301 may be selected and adjusted as needed, and are not specifically limited here.

A wafer stage 4 configured to carry a wafer is provided between the inlet port 201 and the pumping port 301. The process gas entering the chamber body 1 through the inlet port 201 is used for process reaction with the wafer on the wafer stage 4. The shape of the wafer stage 4 may be selected and adjusted as needed, and is not specifically limited here.

The pumping region 5 may be interpreted as including a region between a top horizontal plane of the wafer stage 4 and the top plate 2, a region between sidewalls of the wafer stage 4 and the inner wall of the chamber body 1, and a region between a bottom horizontal plane of the wafer stage 4 and the bottom plate 3.

The first support part 61 is configured to connect the wafer stage 4 and the chamber body 1, and functions to support the wafer stage 4. The shape and size of the first support part 61 may be selected and adjusted as needed, and is not specifically limited here.

A second end of the valve core 72 is liftably inserted into the pumping port 301. A transmission structure for driving the valve core 72 to make lifting movement in the pumping port 301 may be selected and adjusted as needed, and is not specifically limited here. For example, a jacking mechanism, a rack and pinion, a ball screw, a crank link, or the like may be used as the transmission structure to drive, through self-operation, the valve core 72 to make lifting movement relative to the pumping port 301.

The second annulus 74 formed between the valve core 72 and the pumping port 301 may be understood as that: the valve core 72 has a diameter smaller than the pumping port 301. In other words, an annular gap for passage of a gas flow is formed between sidewalls of the valve core 72 and the pumping port 301, and the process gas in the chamber body 1 is discharged to the outside through the annular gap. The shape and size of the valve core 72 may be selected and adjusted as needed, and are not specifically limited here. A distance between the sidewall of the valve core 72 and the pumping port 301, i.e., an annulus thickness of the second annulus 74, may be determined by flow diversion calculation, and then the diameter of the valve core 72 and/or the pumping port 301 may be designed according to the determined distance.

The first annulus 73 formed between the valve plate 71 and the bottom plate 3, as shown in FIGS. 1a and 1b, may be understood as that the valve core 72 is moved up to a certain position in the chamber body 1 so that an annular region is formed between a side end face of the valve plate 71 opposite to the bottom plate 3 and the bottom plate 3, and serves as the first annulus 73. As the valve plate 71 is moved up, the valve plate 71 is gradually moved away from the bottom plate 3, and a volume of the first annulus 73 is gradually increased, so that the flow rate of the process gas passing through the first annulus 73 is increased. As the valve plate 71 is moved down, the valve plate 71 gradually approaches the bottom plate 3, and the volume of the first annulus 73 is gradually reduced, so that the flow rate of the process gas passing through the first annulus 73 is also reduced. The lifting movement of the valve plate 71 may be used to adjust the volume of the first annulus 73, and thereby control the pumping efficiency of the pumping port 301.

The size and shape of the valve plate 71 may be selected and adjusted as needed, and are not specifically limited here. For example, the valve plate 71 may cover the pumping port 301, and then an annular region between the side end face of the valve plate 71 opposite to the bottom plate 3 and the bottom plate 3 is the first annulus 73. Alternatively, the valve plate 71 has a shape matched with a shape of the pumping port 301, and then an annular region between the side end face of the valve plate 71 opposite to the bottom plate 3 and the pumping port 301 is the first annulus 73.

The first annulus 73, the second annulus 74, and the pumping region 5 disposed coaxially, as shown in FIGS. 1a and 1b, may be understood as that centers of the first annulus 73, the second annulus 74, the pumping region 5, and the pumping port 301 are all on the same vertical line (as shown by the dash-dot line in FIGS. 1a and 1b). Since the first annulus 73, the second annulus 74, the pumping region 5, and the pumping port 301 are all symmetrical structures, a uniform gas flow field will be formed when the process gas is pumped out. The process gas will uniformly flow through the pumping region 5, the first annulus 73, and the second annulus 74 in sequence from different directions of 360 degrees simultaneously, thereby avoiding a non-uniform gas flow.

In use of the reaction chamber 100 provided in the embodiments of the present disclosure, the process gas is delivered into the chamber body 1 through the inlet port 201, and used for process reaction with the wafer on the wafer stage 4. When the gas in the chamber body 1 is pumped through the pumping port 301, the valve core 72 is moved up to the first working position, and the process gas uniformly flows through the pumping region 5, the first annulus 73, and the second annulus 74 in sequence, before being discharged out of the chamber body 1 through the pumping port 301. By adjusting the first working position of the valve core 72, a flow rate of the process gas flowing through the first annulus 73, and thus a gas pressure in the chamber body 1, can be controlled.

According to an embodiment of the present disclosure, since the valve core 72 is liftably inserted into the pumping port 301, and the first annulus 73, the second annulus 74, the pumping region 5, and the pumping port 301 are disposed coaxially to form symmetrical structures, when pumped out, the process gas forms a uniform gas flow field in the first annulus 73, the second annulus 74, and the pumping region 5, and will uniformly flow through the pumping region 5, the first annulus 73, and the second annulus 74 in sequence from different directions of 360 degrees simultaneously, so that the gas in a space around the wafer stage 4 can be pumped into the pumping port 301 through the uniform gas flow field, thereby ensuring the uniformity in the wafer etching process results.

In one example, the reaction chamber 100 further includes a flow sensor configured to detect a gas flow rate through the pumping part 7. When the detected gas flow rate passing through the pumping part 7 is less than 50 standard cubic centimeter per minute (sccm, a unit of volume flow) to 2000 sccm, a height of the first working position of the valve core 72 is adjusted.

In one example, the reaction chamber 100 further includes a pressure sensor configured to detect an internal process pressure the chamber body 1. When the detected internal process pressure of the chamber body 1 is less than 1 millitorr (mTorr) to 100 mTorr, a height of the first working position of the valve core 72 is adjusted.

In one example, in operation of the reaction chamber 100, an internal process pressure of the chamber body 1 may be kept within a range of 1 mTorr to 100 mTorr, an internal temperature of the chamber body 1 may be kept within a range of 0° C. to 100° C., and a gas flow rate may be kept within a range of 50 sccm to 2000 sccm.

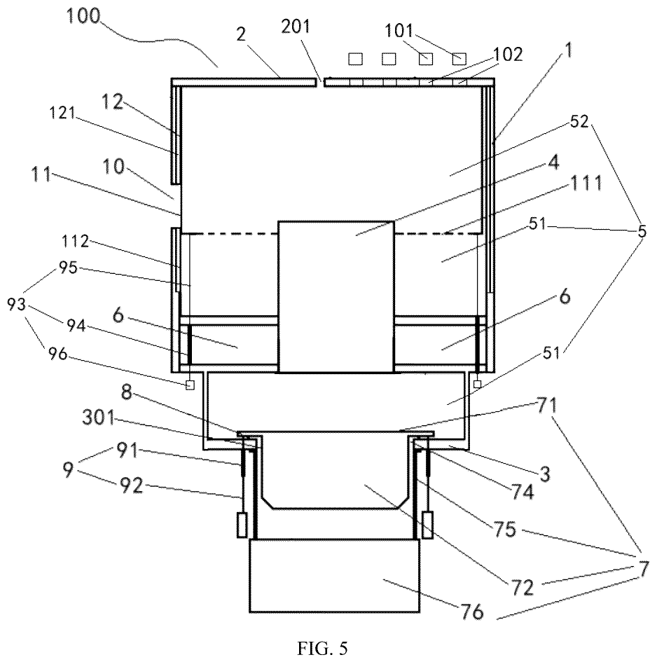

In one example, as shown in FIGS. 1a, 1b, and 5, the reaction chamber 100 further includes a radio frequency source 101 and a dielectric window 102. The radio frequency source 101 is disposed opposite to the dielectric window 102 in the top plate 2, and radio frequency energy generated by the radio frequency source 101 is transmitted into the chamber body 1 through the dielectric window 102 to excite plasma generation by the introduced process gas.

In one implementation, the pumping part 7 may further include a valve body 75 disposed outside the chamber body 1 and connected to the pumping port 301. An inner wall diameter of the valve body 75 is greater than a diameter of the valve core 72. A second end of the valve core 72 is liftably inserted into the pumping port 301 and the valve body 75. A second annulus 74 is formed between the valve core 72 and the pumping port 301, and between the valve core 72 and an inner wall of the valve body 75.

According to the embodiments of the present disclosure, it should be noted that: a second end of the valve core 72 is liftably inserted into the pumping port 301 and the valve body 75, where a transmission structure for driving the valve core 72 to make lifting movement in the valve body 75 may be selected and adjusted as needed, and is not specifically limited here. For example, a jacking mechanism, a rack and pinion, a ball screw, a crank link, or the like may be used as the transmission structure to drive, through self-operation, the valve core 72 to make lifting movement relative to the pumping port 301.

The second annulus 74 formed between the valve core 72 and the pumping port 301, and between the valve core 72 and an inner wall of the valve body 75, may be understood as that an annular gap between the valve core 72 and the pumping port 301, and an annular gap between the valve core 72 and the inner wall of the valve body 75, jointly form the second annulus 74. When the valve core 72 is moved up, an increased part of the valve core 72 is disposed in the valve body 75, and the second end of the valve core 72 is also moved up as the valve core 72, causing a length of the formed second annulus 74 reduced accordingly. When the length of the second annulus 74 is relatively small, a low flow resistance is present through the second annulus 74, so that a gas flow rate passing through the second annulus 74 is increased, while an internal process pressure of the chamber body 1 is reduced. When the valve core 72 is moved down, a reduced part of the valve core 72 is disposed in the valve body 75, and the second end of the valve core 72 is also moved down as the valve core 72, causing the length of the formed second annulus 74 increased accordingly. When the length of the second annulus 74 is relatively large, a high flow resistance is present through the second annulus 74, so that the gas flow rate passing through the second annulus 74 is reduced, while the internal process pressure of the chamber body 1 is increased.

The shape and size of the valve body 75 may be selected and adjusted as needed, and are not specifically limited here, as long as the valve core 72 is allowed to be moved up and down in the valve body 75.

According to an embodiment of the present disclosure, the valve core 72 may be adjusted in a liftable manner to control the length of the second annulus 74, thereby controlling an internal air pressure of the chamber body 1, and adjusting the flow resistance and flow rate of the process gas when the process gas is pumped.

In one example, the valve body 75 is a hollow cylinder, the valve core 72 is a cylinder, the valve core 72 is liftably inserted into the pumping port 301 and the valve body 75, and the second annulus 74 is formed between the valve core 72 and the pumping port 301, and between the valve core 72 and an inner wall of the valve body 75.

In one example, the valve core 72 is an inverted cone, the valve body 75 is fitted to the sidewall of the valve core 72, the valve core 72 is liftably inserted into the pumping port 301 and the valve body 75, and the second annulus 74 is formed between the valve core 72 and the pumping port 301, and between the valve core 72 and an inner wall of the valve body 75.

In one implementation, the pumping part 7 may further include a pump body 76 connected to the pumping port 301 via the valve body 75.

According to the embodiments of the present disclosure, it should be noted that: the pump body 76 may adopt any pump structure in the existing art, as long as the gas inside the chamber body 1 can be pumped out.

According to the embodiment of the present disclosure, pumping of the process gas from the chamber body 1 can be accelerated. Meanwhile, before the process reaction, air inside the chamber body 1 can be pumped out by the pump body 76, so that the interior of the chamber body 1 is in a vacuum state, and the requirement of the wafer process reaction is met.

In one implementation, when the valve core 72 is in a second working position (as shown in FIG. 5), the valve plate 71 contacts the bottom plate 3 to close the pumping port 301.

According to the embodiment of the present disclosure, in the wafer process reaction, the chamber body 1 may form a closed reaction space by controlling the valve core 72 to move to the second working position, thereby meeting the requirement of wafer process reaction, and preventing leakage of the process gas from the chamber body 1 through the pumping port 301.

As shown in FIGS. 1a, 1b and 5, in one implementation, the reaction chamber 100 may further include a seal ring 8 provided at the pumping port 301. When the valve core 72 is in the second working position, the valve plate 71 contacts the seal ring 8.

According to the embodiments of the present disclosure, it should be noted that: the material and number of seal rings 8 are not specifically limited here, as long as the sealing effect is met. For example, one seal ring 8 may be provided at the pumping port 301, and for another example, nested double-layer seal rings 8 may be provided at the pumping port 301.

The seal ring 8 provided at the pumping port 301 may be understood as that the seal ring 8 is connected to an outer edge of the pumping port 301. It may be also understood as that the seal ring 8 is sleeved outside the pumping port 301 and connected to the bottom plate 3.

According to an embodiment of the present disclosure, the provision of the seal ring 8 can enhance the sealing effect of the valve plate 71 on the pumping port 301.

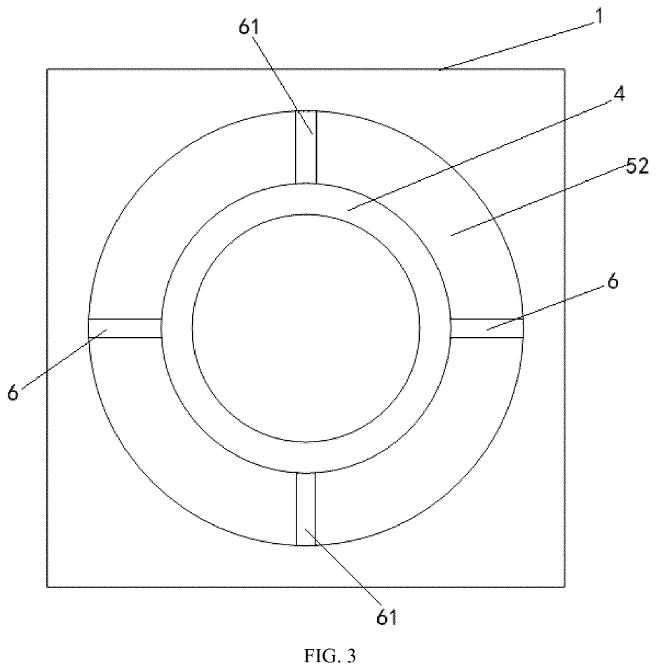

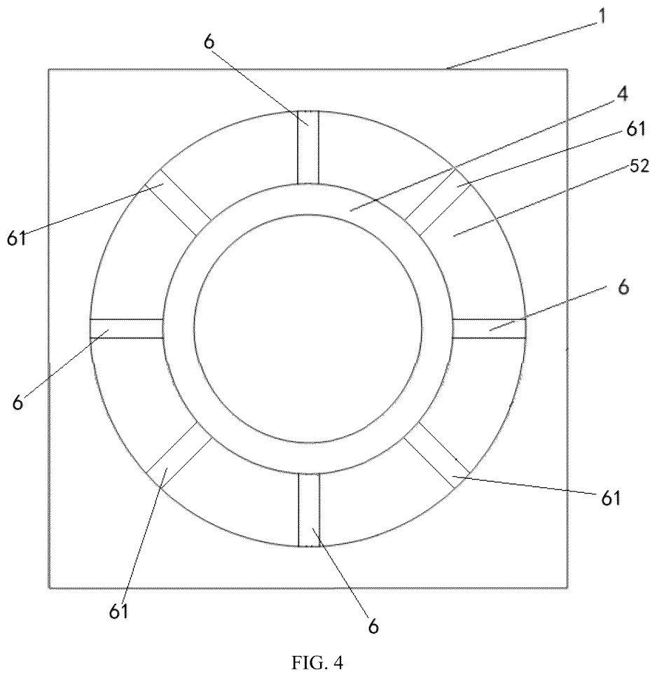

As shown in FIGS. 3 and 4, in one implementation, a plurality of first support parts 61 are provided and uniformly arranged along a circumferential direction of the wafer stage 4.

According to the embodiments of the present disclosure, it should be noted that: the number of first support parts 61 may be selected and adjusted as needed, and may be, for example, 2, 4, 5, 6, 7 or 8.

The first support parts 61 may have the same size.

According to an embodiment of the present disclosure, due to the plurality of first support parts 61 uniformly arranged, the pumping region 5 between the wafer stage 4 and the chamber body 1 is uniformly divided into a plurality of subregion, and when pumped, the process gas uniformly passes through the subregion of the pumping region 5 between the first support parts 61. Meanwhile, the plurality of first support parts 61 can improve the stability of the wafer stage 4.

In one example, a plurality of first support parts 61 are uniformly arranged along the circumferential direction of the wafer stage 4 in a first horizontal plane of the wafer stage 4, and a plurality of first support parts 61 are uniformly arranged along the circumferential direction of the wafer stage 4 in a second horizontal plane of the wafer stage 4. The first horizontal plane and the second horizontal plane are spaced apart in the vertical direction. Projections of the first support parts 61 in the first horizontal plane and projections of the first support parts 61 in the second horizontal plane are overlapped with each other in the vertical direction, or projections of the first support parts 61 in the first horizontal plane and projections of the first support parts 61 in the second horizontal plane are staggered in the vertical direction. The process gas passes through a subregion of the pumping region 5 between two adjacent first support parts 61 in the same horizontal plane.

In one example, a plurality of first support parts 61 are uniformly arranged along the circumferential direction of the wafer stage 4 in a first horizontal plane of the wafer stage 4, and a plurality of first support parts 61 are uniformly arranged along the circumferential direction of the wafer stage 4 in a second horizontal plane of the wafer stage 4. The first horizontal plane and the second horizontal plane are spaced apart in the vertical direction. Projections of the first support parts 61 in the first horizontal plane and projections of the first support parts 61 in the second horizontal plane are overlapped with each other in the vertical direction, or projections of the first support parts 61 in the first horizontal plane and projections of the first support parts 61 in the second horizontal plane are staggered in the vertical direction. The process gas passes through a subregion of the second pumping region 51 between two adjacent first support parts 61 in the same horizontal plane.

In one implementation, a cross section of the first support part 61 in the horizontal direction has a width being one tenth to one half of a radius of the wafer stage 4.

According to the embodiments of the present disclosure, it should be noted that: the width of the cross section of the first support part 61 in the horizontal direction may be understood as that the first support part 61 has a surface for blocking a gas flow in the pumping region 5, a length of the surface is a distance between the wafer stage 4 and the inner wall of the chamber body 1, and a width of the surface is the width of the cross section of the first support part 61 in the horizontal direction. The width of the first support part 61 may be selected and adjusted as needed, and is not specifically limited here. For example, if the number of first support parts 61 is increased, the width of each first support part 61 is decreased, thereby reducing the influence of the first support part 61 on the uniform gas flow in the pumping region 5.

According to an embodiment of the present disclosure, by providing the plurality of first support parts 61 of a smaller width and uniformly distributed, when the process gas flows through the pumping region 5, a blocking area of the first support parts 61 to the process gas flow is reduced, and the process gas can uniformly flow through the pumping region 5.

In one example, the reaction chamber 100 is provided with a plurality of first support parts 61 uniformly arranged along the circumferential direction of the wafer stage 4, and a width of a cross section of each first support part 61 in the horizontal direction gradually decreases as the number of first support parts 61 increases. For example, the reaction chamber 100 is provided with two first support parts 61 uniformly arranged along the circumferential direction of the wafer stage 4, and the width of the cross section of each first support part 61 in the horizontal direction is one half of a radius of the wafer stage 4. The reaction chamber 100 is provided with four first support parts 61 uniformly arranged along the circumferential direction of the wafer stage 4, and the width of the cross section of each first support part 61 in the horizontal direction is a quarter of the radius of the wafer stage 4. The reaction chamber 100 is provided with five first support parts 61 uniformly arranged along the circumferential direction of the wafer stage 4, and the width of the cross section of each first support part 61 in the horizontal direction is one fifth of the radius of the wafer stage 4. The reaction chamber 100 is provided with eight first support parts 61 uniformly arranged along the circumferential direction of the wafer stage 4, and the width of the cross section of each first support part 61 in the horizontal direction is one eighth of the radius of the wafer stage 4.

As shown in FIGS. 1a, 1b, 2 and 5, in one implementation, the first support part 61 has a tubular structure, a first port of the first support part 61 is communicated with the chamber body 1, and a second port of the first support part 61 is communicated with the wafer stage 4.

A power connection line of the wafer stage 4 and/or a pipeline (gas and/or liquid) of the reaction chamber 100 are led out of the chamber body 1 through the second port, an internal pipeline of the first support part 61, and the first port in sequence.

According to the embodiments of the present disclosure, it should be noted that: the power connection line of the wafer stage 4 may include a power supply line (e.g., a high voltage direct current power supply line, a heating power supply line), a signal line (e.g., a thermocouple connection line), and the like, which is not specifically limited here.

The pipeline may include: a gas pipeline (e.g., a helium (He) pipeline, a compressed dry air (CDA) pipeline), a coolant pipeline, and the like.

According to an embodiment of the present disclosure, the tubular structure of the first support part 61 may prevent the power connection line of the wafer stage 4 and/or the pipeline of the reaction chamber 100 from being exposed to the pumping region 5.

In one example, the power connection line of the wafer stage 4 and/or the pipeline of the reaction chamber 100 maybe accommodated in different first support parts 61, respectively, or may be accommodated in groups in different first support parts 61. For example, the power supply line, the signal line, the gas pipeline, and the coolant pipeline are respectively accommodated in different first support parts 61, so that an influence on the uniform gas flow due to all lines accommodated in the same first support part 61 can be avoided, while maintenance and device safety are facilitated.

According to an embodiment of the present disclosure, since the power connection line of the wafer stage 4 and/or the pipeline of the reaction chamber 100 are provided in different first support parts 61, the design width of each first support part 61 can be further minimized, thereby reducing the influence of the first support part 61 on the uniform gas flow in the pumping region 5.

As shown in FIGS. 1a, 1b and 5, in one implementation, the reaction chamber 100 may further include a first jacking mechanism 9 including a first tubular body 91 and a rod body 92. The first tubular body 91 is connected to the bottom plate 3, one end of the rod body 92 is slidably inserted into the first tubular body 91, the other end of the rod body 92 extends into the chamber body 1 to be connected to the valve plate 71, and the rod body 92 configured to drive the valve plate 71 and the valve core 72 to make lifting movement.

According to the embodiments of the present disclosure, it should be noted that: the rod body 92 configured to drive the valve plate 71 and the valve core 72 to make lifting movement may be understood as that the rod body 92 drives the valve core 72 to move between the first working position and the second working position, that is, the rod body 92 controls opening or closing of the pumping part 7.

The slidable manner of the rod body 92 relative to the first tubular body 91 may be selected and adjusted as needed, and is not specifically limited here.

The material, size and position of the first tubular body 91 may be selected and adjusted as needed. For example, the first tubular body 91 may be a seal bellows.

According to an embodiment of the present disclosure, the valve plate 71 and the valve core 72 can be driven by the first jacking mechanism 9 to perform lifting movement smoothly and stably.

In one example, the first tubular body 91 is disposed outside the chamber body 1, one end of the rod body 92 passes through the first tubular body 91 to be connected to the valve plate 71 inside the chamber body 1, and the other end of the rod body 92 passes through the first tubular body 91 to be connected to a motor disposed outside the chamber body 1. The motor is configured to drive the rod body 92 to slide in a vertical direction relative to the first tubular body 91.

According to an embodiment of the present disclosure, since the first tubular body 91 is disposed outside the chamber body 1, the process gas inside the chamber body 1 can be prevented from corroding the first tubular body 91, and thereby the service life of the first tubular body 91 is extended.

In one implementation, the reaction chamber 100 may include a plurality of first jacking mechanisms 9 uniformly arranged along a circumferential direction of the valve plate 71.

According to the embodiments of the present disclosure, it should be noted that: the plurality of first jacking mechanisms 9 may be understood as at least two first jacking mechanisms 9.

According to an embodiment of the present disclosure, the plurality of first jacking mechanisms 9 uniformly arranged can enable more stable lifting movement of the valve plate 71 and the valve core 72, while avoiding the problem of asymmetrical structures of the first annulus 73 and the second annulus 74 caused by deflection of the valve core 72 and the valve plate 71 in the axial direction under non-uniform stress, thereby ensuring uniform gas pumping at the pumping port 301.

As shown in FIGS. 1a and 1b, in one implementation, the reaction chamber 100 may further include a wafer transfer port 10 and a first liner 11.

The wafer transfer port 10 is in communication with an interior of the chamber body 1, and configured to transfer a wafer to the wafer stage 4.

The first liner 11 is slidably connected to the inner wall of the chamber body 1, and slidably sleeved outside of the wafer stage 4. The first liner 11 is provided with a vent hole 111, through which a first pumping region 52 close to the inlet port 201 is communicated with a second pumping region 51 close to the pumping port 301. When the first liner 11 is in a third working position, the wafer transfer port 10 is in communication with the first pumping region 52.

According to the embodiments of the present disclosure, it should be noted that: the wafer transfer port 10 is located in substantially the same horizontal plane as the wafer stage 4 to facilitate transfer of the wafer, but the arrangement of the two may be selected and adjusted as needed, as long as wafer transport can be implemented.

The first liner 11 may be understood as consisting of three parts, i.e., a first part slidably connected to the inner wall of the chamber body 1, a second part slidably connected to the sidewall of the wafer stage 4, and a third part between the first part and the second part, and the third part is provided with the vent hole 111. The slidable manner of the first liner 11 relative to the inner wall of the chamber body 1, and the slidable manner of the first liner 11 relative to the wafer stage 4, may be selected and adjusted as needed, and are not specifically limited here.

The third working position may be understood as a position to which the first liner 11 is lowered so that the wafer transfer port 10 is in communication with an interior of the chamber body 1. The specific position may be selected and adjusted as needed, and is not specifically limited here.

The number, shape and size of vent holes 111 may be selected and adjusted as needed, and are not specifically limited here. The position of the vent hole 111 may be selected and adjusted as needed. For example, vent holes 111 are uniformly arranged at positions of the first liner 11 opposite to the top plate 2. When the pumping part 7 is opened, the process gas enters the second pumping region 51 from the first pumping region 52 through the vent hole 111, and then is discharged from the chamber body 1 through the first annulus 73 and the second annulus 74.

A working process of the first liner 11 is as follows: in the wafer etching process, when the first liner 11 is in the third working position, the wafer transfer port 10 is in communication with the first pumping region 52, and a wafer is delivered by a manipulator into the chamber body 1 through the wafer transfer port 10, and placed on the wafer stage 4. The manipulator is withdrawn from the chamber body 1, and the first liner 11 is moved from the third working position to the fourth working position to close the wafer transfer port 10. Process reaction is performed in the chamber body 1, and when the process is finished, the first liner 11 is moved back to the third working position, and the manipulator enters the chamber body 1 again to fetch the wafer. The chamber body 1 and the first liner 11 are respectively designed with regions for passage of the wafer transfer port.

According to an embodiment of the present disclosure, since the first liner 11 is slidably connected to the inner wall of the chamber body 1, opening and closing of the wafer transfer port 10 can be controlled. Meanwhile, adhering impurities generated in the process reaction may adhere to the first liner 11, thereby preventing corrosion to the chamber body 1 and extending the service life of the chamber body 1.

In one example, the reaction chamber 100 further includes a second liner 12 connected to the top plate 2 and a side plate of the chamber body 1. The second liner 12 is provided with an opening in communication with the inlet port 201. A second wafer transfer port 121 is formed between the second liner 12 and the first liner 11. When the first liner 11 is in the third working position, the wafer transfer port 10 is in communication with the first pumping region 52 via the second wafer transfer port 121.

According to an example of the present disclosure, the provision of the second liner 12 can further reduce the corrosion of the process gas to the chamber body 1, and extend the service life of the chamber body 1. Meanwhile, the second liner 12 is arranged opposite to the first liner 11, so that the gas flow field in the wafer reaction region is more uniform.

As shown in FIG. 5, in one implementation, when the first liner 11 is in a fourth working position, the first liner 11 closes the wafer transfer port 10.

According to the embodiments of the present disclosure, it should be noted that: the fourth working position may be understood as a position to which the first liner 11 is raised so that the wafer transfer port 10 is isolated from being communicated with the interior of the chamber body 1. The specific position may be selected and adjusted as needed, and is not specifically limited here.

According to an embodiment of the present disclosure, when the first liner 11 is moved to the fourth working position, a closed environment can be formed in the chamber body 1, so that the requirement of the wafer process reaction is met.

In one implementation, the reaction chamber 100 may further include a first heater 112 disposed in the inner wall of the chamber body 1 at a position corresponding to the first liner 11, and configured to heat the first liner 11. In the wafer etching process, the first heater 112 heats the first liner 11 so that a temperature of the first liner 11 is increased, which is beneficial to plasma ignition. When one wafer etching process on the wafer is completed, the temperature of the first liner 11 may be reduced without plasma. The first heater 112 may be controlled to heat the first liner 11 in a time period without plasma, so that in a second wafer etching process, the first liner 11 is still at a temperature favorable for the wafer etching process. As a result, each wafer is in a stable process environment, and the uniformity in the process results of different wafers can be improved.

According to the embodiments of the present disclosure, it should be noted that: the first heater 112 disposed in the inner wall of the chamber body 1 may be understood as that the first heater 112 is embedded into the inner wall of the chamber body 1, or the inner wall of the chamber body 1 is provided with a recess into which the first heater 112 is disposed. The first heater 112 should have an inner diameter as equal as possible to that of the chamber body 1, so that a uniform gas flow field can be formed inside the chamber body 1 in the wafer etching process.

The first heater 112 provided at a position corresponding to the first liner 11 may be understood as that a heating region of the first heater 112 should cover at least an active region of the first liner 11, so that the first heater 112 can heat each region of the first liner 11.

The heating mode of the first heater 112 is not specifically limited here, as long as heat can be transferred to the first liner 11. For example, the first heater 112 may heat the first liner 11 by radiant heating or by contact thermal conduction.

According to an embodiment of the present disclosure, the first liner 11 provided in the chamber body 1 can enable byproducts generated in the wafer etching process to adhere to the first liner 11, thereby preventing the byproducts from adhering to the chamber body 1 and causing particle contamination of the chamber body 1, and extending the service life of the chamber body 1. With the first liner 11 heated by the first heater 112, the temperature of the first liner 11 can be increased in the wafer etching process, thereby facilitating plasma ignition in the chamber body 1, while reducing excessive deposition of byproducts on the first liner 11 in the reaction process.

In one implementation, a plurality of first heaters 112 are provided and arranged along a vertical direction, and each of the plurality of first heaters 112 is electrically connected to a first controller. The first controller is configured to control the plurality of first heaters 112 to heat different regions of the first liner 11 at respective temperatures. The plurality of first heaters 112 arranged in the vertical direction may enable heating at different regions of the first liner 11. The plurality of first heaters 112 controlled by the first controller may have different temperatures.

According to the embodiments of the present disclosure, it should be noted that: the plurality of first heaters 112 may be disposed at any position of the chamber body 1 corresponding to the first liner 11, as long as the plurality of first heaters 112 can heat different regions of the first liner 11 respectively. For example, the plurality of first heaters 112 are annularly arranged outside the first liner 11 in the vertical direction, so that a combination of the plurality of first heaters 112 can cover the entire outer wall region of the first liner 11. For another example, the plurality of first heaters 112 are staggered in the vertical direction, and respectively distributed in a plurality of outer wall regions of the first liner 11, so that the entire outer wall region of the first liner 11 can be heated through thermal conduction by the plurality of first heaters 112.

The temperature of each first heater controlled by the first controller may be selected and adjusted as needed, and is not specifically limited here. For example, if the temperature of the first liner 11 is required to be kept between 100° C. and 150° C. in the wafer etching process, the first controller may be used to control one part of the first heaters 112 to heat an upper region of the first liner 11 to a temperature between 100° C. and 120° C., while controlling the other part of the first heaters 112 to heat a lower region of the first liner 11 to a temperature between 120° C. and 150° C.

According to an embodiment of the present disclosure, by controlling the temperatures of the plurality of first heaters 112, the first controller can further adjust heating temperatures at different regions of the first liner 11, thereby improving the controllability of the temperature of the first liner 11 in the wafer etching process. Meanwhile, according to byproduct deposition conditions at different regions of the inner sidewall of the first liner 11, one or more first heaters 112 may be controlled to heat regions with serious byproduct deposition in a targeted and accurate manner, to improve the byproduct deposition conditions on the inner sidewall of the first liner 11.

In one implementation, the reaction chamber 100 may further include a temperature sensor. The temperature sensor is connected to the first liner 11 and the first heater 112, and configured to detect a temperature of the first liner 11, and feed back a temperature detection result of the first liner 11 to the first heater 112.

When the detected temperature of the first liner 11 does not meet the temperature required in the wafer etching process, the heating temperature of the first heater 112 is increased to further adjust the temperature of the first liner 11.

According to the embodiments of the present disclosure, it should be noted that: the temperature sensor may be any detection device capable of temperature measurement in the existing art, and may be selected and adjusted as needed, and is not specifically limited here, as long as temperature detection of the first liner 11 can be implemented.

According to an embodiment of the present disclosure, based on the temperature detection result of the temperature sensor provided, the temperature of the first liner 11 can be precisely adjusted by the first heater 112, so that the controllability of the temperature of the first liner 11 is further improved, and plasma ignition in the chamber body 1 is facilitated, while excessive deposition of byproducts on the first liner 11 in the reaction process is reduced.

In one example, the temperature sensor may be an infrared temperature sensor.

In one example, the heating temperature of the first heater 112 is adjusted when the temperature sensor detects that the temperature of the first liner 11 does not meet the temperature range requirement of between 100° C. and 150° C.

In one example, the temperature sensor is connected to the first liner 11 and the first controller, and configured to detect a temperature of the first liner 11, and feed back a temperature detection result of the first liner 11 to the first controller. When the detected temperature of the first liner 11 does not meet the temperature required in the wafer etching process, the first controller adjusts the heating temperature of the first heater 112, to further adjust the temperature of the first liner 11.

In one example, two temperature sensors are provided in the reaction chamber 100. A first temperature sensor is connected to the first liner 11 and the first heater 112, and configured to detect a temperature of the first liner 11, and feed back a temperature detection result of the first liner 11 to the first heater 112. A second temperature sensor is connected to the chamber body 1 and the first heater 112, and configured to detect a temperature of the chamber body 1, and feed back a temperature detection result of the chamber body 1 to the first heater 112.

In one example, in operation of the reaction chamber 100, an internal temperature of the chamber body 1 may be kept between 60° C. and 100° C., the temperature of the first liner 11 may be kept between 100° C. and 150° C., and the high-temperature first liner 11 can prevent byproduct deposition.

In one implementation, the first heater 112 may be a radiant heater. The radiant heater has a radiant heating end disposed toward the first liner 11.

According to the embodiments of the present disclosure, it should be noted that: the type of the radiant heater may be selected and adjusted as needed, and is not specifically limited here. For example, a radiant heater of a proper wavelength is selected according to the material of the first liner 11. The specific structure of the radiant heater may adopt the structure of any radiant heater in the existing art, which is not specifically limited here. For example, the radiant heater may be heater in the form of an embedded heating wire.

According to an embodiment of the present disclosure, the radiant heater may be used to heat the first liner 11 rapidly in a thermal conduction mode, thereby improving the heating efficiency of the first liner 11.

In one example, the radiant heater may be an infrared tube heater.

In one example, the reaction chamber 100 is further provided with a vacuum adapter flange, through which a power supply connection line is connected to the first heater 112 to supply power to the first heater 112.

In one example, a thermal insulation layer is further provided between the first heater 112 and the inner wall of the chamber body 1, to prevent the temperature of the first heater 112 from influencing the chamber body 1, and extend the service life of the chamber body 1.

In one implementation, the first liner 11 is provided with a vent hole 111 for communicating the first pumping region 52 with the second pumping region 51, so that the first pumping region 52 and the second pumping region 51 are kept at the same pressure. The pumping region 5 includes the first pumping region 52 and the second pumping region 51. Spatial volumes of the first pumping region 52 and the second pumping region 51 will vary with the working position of the first liner 11. For example, when the first liner 11 slides in a direction toward the top plate 2, a distance from the top plate 2 to the first liner 11 will be decreased, while a distance from the bottom plate 3 to the first liner 11 will be increased. Therefore, the spatial volume of the first pumping region 52 is decreased, while the spatial volume of the second pumping region 51 is increased. When the first liner 11 moves toward the bottom plate 3, the distance from the top plate 2 to the first liner 11 will be increased, while the distance from the bottom plate 3 to the first liner 11 will be decreased. Therefore, the spatial volume of the first pumping region 52 is increased, while the spatial volume of the second pumping region 51 is decreased.

The number, shape and size of vent holes 111 may be selected and adjusted as needed, and are not specifically limited here. The position of the vent hole 111 may be selected and adjusted as needed. For example, vent holes 111 are uniformly arranged in a region of the first liner 11 between the inner wall of the chamber body 1 and the outer wall of the wafer stage 4.

According to an embodiment of the present disclosure, the vent hole 111 in the first liner 11 allows a uniform internal pressure across the chamber body 1, so that a uniform gas flow field can be formed in the first pumping region 52, and the uniformity in the process results is improved.

In one example, the first heater 112 heats the vent hole 111 at a higher temperature than the rest of the first liner 11, so that byproducts generated in the wafer etching process are prevented from depositing into and blocking the vent hole 111.

In one implementation, the first liner 11 may have a third working position and a fourth working position. When the first liner 11 slides to the third working position, the wafer transfer port 10 is in communication with the first pumping region 52. When the first liner 11 slides to the fourth working position, the wafer transfer port 10 is isolated from the first pumping region 52.

A heating region of the first heater 112 includes at least a region in which the first liner 11 is slidable between the third working position and the fourth working position.

According to the embodiments of the present disclosure, it should be noted that: the third working position may be understood as a position to which the first liner 11 slides toward the bottom plate 3 so that the wafer transfer port 10 is in communication with the first pumping region 52. The specific position may be selected and adjusted as needed, and is not specifically limited here.

The fourth working position may be understood as a position to which the first liner 11 slides toward the top plate 2 so that the wafer transfer port 10 is isolated from being communicated with the first pumping region 52. The specific position may be selected and adjusted as needed, and is not specifically limited here.

The heating region may be understood as any position of the first liner 11 opposite to the reaction chamber 100 and enabling heat transfer from the first heater 112 to the first liner 11 to make the first liner 11 heated. In the wafer etching process, the first liner 11 slides to the fourth working position, and the first heater 112 heats the first liner 11, thereby facilitating plasma ignition. When the wafer etching process is completed, the first liner 11 slides to the third working position, and the first heater 112 still heats the first liner 11, so that in a following wafer etching process, the first liner 11 is still at a temperature favorable for the wafer etching process, thereby improving the uniformity in the process results of different wafers.

According to an embodiment of the present disclosure, the heating region of the first heater 112 covers a slidable region of the first liner 11, so that the first liner 11 can be continuously and sufficiently heated, and a stable process environment is formed inside the chamber body 1.

In one implementation, the reaction chamber 100 may further include a second liner 12. The second liner 12 is connected to the inner wall of the chamber body 1 and disposed adjacent to the top plate 2. The second liner 12 is provided with an opening in communication with the inlet port 201. The second liner 12, the first liner 11 and the wafer stage 4 are disposed coaxially, and the second liner 12 has an inner diameter equal to that of the first liner 11.

When the first liner 11 slides to the third working position, the wafer transfer port 10 is in communication with the first pumping region 52. When the first liner 11 slides to the fourth working position, the first liner 11 is jointed with the second liner 12 to form a closed first pumping region 52, and the wafer transfer port 10 is isolated from the closed first pumping region 52. In this case, the wafer stage 4, the first liner 11, the second liner 12 and an interior of the chamber body 1 jointly form a circumferentially symmetrical region.

According to the embodiments of the present disclosure, it should be noted that: the first liner 11 disposed coaxially with the second liner 12 may be understood as that a central axis of the first liner 11 coincides a central axis of the second liner 12.

The third working position may be understood as a lower position to which the first liner 11 slides toward the bottom plate 3 so that the wafer transfer port 10 is in communication with the first pumping region 52. The specific lower position may be selected and adjusted as needed, and is not specifically limited here. When the first liner 11 slides to the third working position, the wafer may be fed into the chamber body 1 through the wafer transfer port 10 and placed on the wafer stage 4.

The fourth working position may be understood as a higher position to which the first liner 11 slides toward the top plate 2 so that the wafer transfer port 10 is isolated from being communicated with the first pumping region 52. The specific higher position may be selected and adjusted as needed, and is not specifically limited here.

The second liner 12 has a shape matched with a shape of the inner wall of the chamber body 1. The second liner 12 may have an annular structure with a varying height, and the first sidewall of the first liner 11 may be an annular sidewall with a varying height, as long as after the first liner 11 slides to the fourth working position and the first liner 11 is jointed with the second liner 12, inner sidewalls of the first liner 11 and the second liner 12 can form a closed and circumferentially symmetrical first pumping region 52 with the chamber body 1.

According to an embodiment of the present disclosure, the second liner 12 enables byproducts generated in the wafer etching process to adhere thereon, thereby further preventing the byproducts from adhering to the chamber body 1 and causing particle contamination of the chamber body 1, and extending the service life of the chamber body 1. Meanwhile, the second liner 12 and the first liner 11 are disposed coaxially and have the same inner diameter, so that the wafer stage 4, the first liner 11, the second liner 12 and an interior of the chamber body 1 jointly form a circumferentially symmetrical region. In the etching process, the wafer may be placed in a circumferentially symmetrical process environment, so that a process gas introduced into the chamber body 1 can form a uniform and circumferentially symmetrical gas flow field around the wafer, while the electrical property of the first liner 11 is also circumferentially symmetrical, thereby maximizing the circumferentially symmetrical uniformity in the wafer process result.

In one example, in the wafer etching process, byproducts such as particles may be generated and adhere to the first liner 11 and the second liner 12, and to prevent particle contamination of the wafer caused by the byproducts falling off from the first liner 11 and the second liner 12, the first liner 11 and the second liner 12 should be cleaned or replaced regularly. Therefore, the first liner 11 and the second liner 12 are detachably disposed in the chamber body 1 to facilitate assembly and disassembly, cleaning, and replacement.

In one example, an inner sidewall of a first sidewall of the first liner 11 has an annular structure extending in the vertical direction, and an inner sidewall of the second liner 12 also has an annular structure extending in the vertical direction, so that a circumferentially symmetrical space structure is formed inside the first liner 11 and the second liner 12 when the two are jointed.

In one example, the second liner 12 is connected to the inner wall of the chamber body 1 by a flange. The flange is connected to a heating device configured to heat the flange, so that the flange conducts the absorbed heat to the second liner 12 and the first liner 11. Meanwhile, in combination with the auxiliary heating of the first liner 11 by the first heater 112, plasma ignition in the chamber body 1 can be further facilitated, while excessive deposition of byproducts on the first liner 11 in the reaction process is reduced.

In one implementation, the reaction chamber 100 may further include a second heater 121. The second heater 121 is disposed in the inner wall of the chamber body 1 at a position corresponding to the second liner 12, and the second heater 121 is electrically connected to a second controller configured to control the second heater 121 to heat the second liner 12 at a set temperature.

In the wafer etching process, the second heater 121 heats the second liner 12 so that a temperature of the second liner 12 is increased, which is beneficial to plasma ignition. When one wafer etching process on the wafer is completed, the temperature of the second liner 12 may be reduced without plasma. The second controller may control the second heater 121 to heat the second liner 12 in a time period without plasma, so that in a second wafer etching process, the second liner 12 is still at a temperature favorable for the wafer etching process. As a result, each wafer is in a stable process environment, and the uniformity in the process results of different wafers can be improved.

According to the embodiments of the present disclosure, it should be noted that: the second heater 121 disposed in the inner wall of the chamber body 1 may be understood as that the second heater 121 is embedded into the inner wall of the chamber body 1, or the inner wall of the chamber body 1 is provided with a recess into which the second heater 121 is disposed. The second heater 121 should have an inner diameter as equal as possible to that of the chamber body 1, so that a uniform gas flow field can be formed inside the chamber body 1 in the wafer etching process.

The second heater 121 provided at a position corresponding to the second liner 12 may be understood as that a heating region of the second heater 121 should cover at least the second liner 12, so that the second heater 121 can heat each region of the second liner 12.

The heating mode of the second heater 121 is not specifically limited here, as long as heat can be transferred to the second liner 12. For example, the second heater 121 may heat the second liner 12 by radiant heating or by contact thermal conduction.

The second heater 121 may be of the same type as, or a different type from, the first heater 112, which may be specifically selected and adjusted as needed, and is not specifically limited here. For example, the second heater 121 is a contact thermal conduction heater, while the first heater 112 is a radiant heater.

The second controller and the first controller may be the same controller for controlling the second heater 121 and the first heater 112 simultaneously. The second controller and the first controller may be two controllers for controlling the second heater 121 and the first heater 112, respectively, which may be specifically selected and adjusted as needed, and is not specifically limited here.

According to an embodiment of the present disclosure, with the second liner 12 heated by the second heater 121, plasma ignition can be facilitated. A stable process environment is formed inside the chamber body 1, and the uniformity in the process results is improved. Meanwhile, the provision of the first controller can improve the controllability of the temperature of the second liner 12 in the wafer etching process.

In one implementation, the reaction chamber 100 may further include: a second support part 6 and a second jacking mechanism 93.

The second support part 6 is disposed between the chamber body 1 and the wafer stage 4, and located outside the first liner 11.

The second jacking mechanism 93 is disposed in the second support part 6. A lifting part 95 of the second jacking mechanism 93 is connected to the first liner 11, and configured to drive the first liner 11 to slide.

According to the embodiments of the present disclosure, it should be noted that: the second support part 6 is configured to connect the wafer stage 4 and the chamber body 1, and functions to support the wafer stage 4. The shape and size of the second support part 6 may be selected and adjusted as needed, and are not specifically limited here.

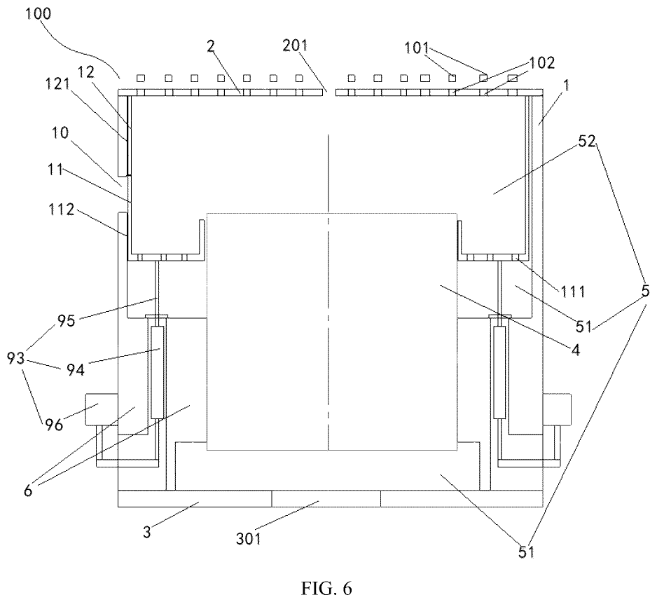

The outside of the first liner 11 may be understood as the lower region of the first liner 11 shown in FIGS. 1a, 1b, 5 and 6. The inside of the first liner 11 may be understood as the interior and upper regions of the first liner 11 shown in FIGS. 1a, 1b, 5 and 6. The second support part 6 is accommodated outside of the first liner 11, while a wafer is accommodated inside the first liner 11.

The second jacking mechanism 93 provided in the second support part 6 may be understood as that the second jacking mechanism 93 is accommodated inside the second support part 6. In an operating state, the lifting part 95 extends out of the second support part 6, and drives the first liner 11 to slide up and down inside the chamber body 1. In a non-operating state, the lifting part 95 is retracted into the second support part 6. In the etching process, only the lifting part 95 of the second jacking mechanism 93 is exposed to the process environment in the chamber body 1, while the rest is hidden in the second support part 6.

According to an embodiment of the present disclosure, since the first liner 11 can block and close the wafer transfer port 10 and is disposed coaxially with the wafer stage 4, the wafer stage 4, the first liner 11 and an interior of the chamber body 1 jointly form a circumferentially symmetrical region. In the etching process, the wafer may be placed in a circumferentially symmetrical process environment, so that a process gas introduced into the chamber body 1 can form a uniform and circumferentially symmetrical gas flow field around the wafer, while the electrical property of the first liner 11 is also circumferentially symmetrical, thereby maximizing the circumferentially symmetrical uniformity in the wafer process result. Further, provided in the first support part 6, the second jacking mechanism 93 is away from a plasma region formed around the wafer during etching and is not exposed in the chamber body 1, so that while the wafer is etched, contamination of the wafer caused by the whole structure of the first jacking mechanism 93 can be avoided, and corrosion of the whole structure of the first jacking mechanism 93 in the etching process can be prevented.

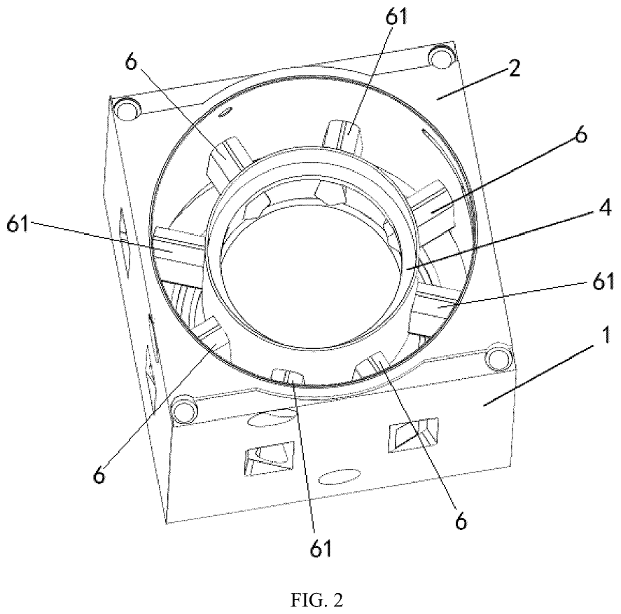

In one example, based on the schematic structural diagram of the opposite second support parts 6 in FIGS. 1a and 1b, a schematic structural diagram of the opposite first support parts 61 (FIG. 2) can be obtained by rotating the reaction chamber 100 by a certain angle along the central axis (dash-dot line) in FIGS. 1a and 1b.

In one example, a plurality of first support parts 61 are uniformly arranged along the circumferential direction of the wafer stage 4 in a first horizontal plane of the wafer stage 4, and a plurality of first support parts 61 are uniformly arranged along the circumferential direction of the wafer stage 4 in a second horizontal plane of the wafer stage 4. The first horizontal plane and the second horizontal plane are spaced apart in the vertical direction. Projections of the first support parts 61 in the first horizontal plane and projections of the first support parts 61 in the second horizontal plane are overlapped with each other in the vertical direction, or projections of the first support parts 61 in the first horizontal plane and projections of the first support parts 61 in the second horizontal plane are staggered in the vertical direction. The process gas passes through a subregion of the second pumping region 511 between two adjacent first support parts 61 in the same horizontal plane. The second support part 6 may be the same as, or different from, the first support part 61, which may be specifically selected and adjusted as needed, and is not specifically limited here. The position of the second support part 6 relative to the first support part 61 may be selected and adjusted as needed, and is not specifically limited here. For example, the second support part 6 and the first support part 61 may be uniformly arranged in the same horizontal plane, or the second support part 6 may be disposed on a longitudinal projection of the first support part 61 in a different horizontal plane. The shape and size of the first support part 61 may be selected and adjusted as needed, and are not specifically limited here.

In one implementation, the lifting part 95 is made of an aluminum alloy material, with a surface coated with an yttria coating.

According to an embodiment of the present disclosure, the aluminum alloy material can extend the service life of the lifting part 95, while the coated yttria coating can prevent contamination of the wafer by the lifting part 95, and enhance the corrosion resistance of the lifting part 95.

In one implementation, the reaction chamber 100 may further include a plurality of second support parts 6 uniformly arranged along a circumferential direction of the wafer stage 4, where each of the plurality of second support parts 6 is provided with a second jacking mechanism 93.

According to the embodiments of the present disclosure, it should be noted that: the number of the plurality of second support parts 6 may be selected and adjusted as needed, and may be, for example, 2 or 4.

According to an embodiment of the present disclosure, due to the plurality of second support parts 6 uniformly arranged, the second pumping region 51 is uniformly divided into a plurality of subregion, and when pumped, the process gas can uniformly pass through the subregion of the second pumping region 51. Meanwhile, the plurality of second support parts 6 can improve the stability of the wafer stage 4.

In one example, a plurality of second support parts 6 are uniformly arranged along the circumferential direction of the wafer stage 4 in a first horizontal plane of the wafer stage 4, and a plurality of second support parts 6 are uniformly arranged along the circumferential direction of the wafer stage 4 in a second horizontal plane of the wafer stage 4. The first horizontal plane and the second horizontal plane are spaced apart in the vertical direction. Projections of the second support parts 6 in the first horizontal plane and projections of the second support parts 6 in the second horizontal plane are overlapped with each other in the vertical direction, or projections of the second support parts 6 in the first horizontal plane and projections of the second support parts 6 in the second horizontal plane are staggered in the vertical direction. The process gas passes through a subregion of the second pumping region 51 between two adjacent second support parts 6 in the same horizontal plane.

As shown in FIGS. 1a, 1b, 5 and 6, in one implementation, the second jacking mechanism 93 may further include a second tubular body 94. The second tubular body 94 is disposed in the second support part 6. One end of the lifting part 95 is slidably inserted into the second tubular body 94 to reduce direct contact between the lifting part 95 and the second support part 6, while the other end of the lifting part 95 is connected to the first liner 11.

According to the embodiments of the present disclosure, it should be noted that: the sliding mechanism enabling the lifting part 95 to slide relative to the second tubular body 94 may be selected and adjusted as needed, and is not specifically limited here. For example, the sliding mechanism is a rack and pinion, a ball screw, a crank link, a pneumatic lever, a hydraulic lever, or the like. An outer wall of the lifting part 95 may be directly and slidably connected to an inner wall of the second tubular body 94, or may be indirectly and slidably connected to the inner wall of the second tubular body 94 by a connector.

The second tubular body 94 in the first support part 6 may be understood as that the second tubular body 94 is always located in the first support part 6, and does not move with the lifting movement of the lifting part 95.

According to an embodiment of the present disclosure, the second tubular body 94 in the second support part 6 cancan reduce the influence on the process environment of wafer etching by the direct contact between the lifting part 95 and the second support part 6, while extending the service life of the lifting part 95.

As shown in FIGS. 1a, 1b, 5 and 6, in one example, the second jacking mechanism 93 further includes a drive unit 96 connected to the lifting part 95. The drive unit 96 is disposed outside the chamber body 1, and configured to control lifting movement of the lifting part 95.

According to an example of the present disclosure, the drive unit 96 outside the chamber body 1 will not additionally occupy an interior space of the reaction chamber 100, while facilitating maintenance of the second jacking mechanism 93.

In one example, the drive unit 96 employs a clean cylinder mechanism or a hydraulic cylinder mechanism.

In one implementation, the second tubular body 94 is a vacuum bellows made of a corrosion resistant stainless steel material.

According to an embodiment of the present disclosure, the vacuum bellows made of a corrosion resistant stainless steel material can extend the service life of the second tubular body 94. Meanwhile, since the second tubular body 94 is disposed in the second support part 6 and away from a plasma region formed around the wafer during etching, contamination of the wafer can be avoided.

An embodiment of the present disclosure further provides a wafer etching device, including: the reaction chamber 100 according to any of the above embodiments of the present disclosure.

In operation of the wafer etching device, the valve core 72 is controlled to slide to a first working position so that a process gas subjected to process reaction in the chamber body 1 enters the second region from the first region through the vent hole 111, and then sequentially flows through the first annulus 73 and the second annulus 74 to be pumped out by the pump body 76. The first liner 11 is controlled to slide to a third working position so that the wafer subjected to the process reaction is fetched through the wafer transfer port 10.

According to an embodiment of the present disclosure, since the valve core 72 is liftably inserted into the pumping port 301, and the first annulus 73, the second annulus 74, the pumping region 5, and the pumping port 301 are disposed coaxially to form symmetrical structures, when pumped out, the process gas forms a uniform gas flow field in the first annulus 73, the second annulus 74, and the pumping region 5, and will uniformly flow through the pumping region 5, the first annulus 73, and the second annulus 74 in sequence from different directions of 360 degrees simultaneously, so that the gas in a space around the wafer stage 4 can be pumped into the pumping port 301 through the uniform gas flow field, thereby ensuring the uniformity in the wafer etching process results.

In one example, when the chamber body 1 is provided with a first liner 11, the first liner 11 is controlled to slide to the third working position so that a wafer is delivered onto the wafer stage 4 through a wafer transfer port 10, and then the first liner 11 is controlled to slide to the fourth working position, and the valve core 72 is controlled to slide to the first working position, so that the air in the chamber body 1 is pumped to a vacuum state by the pumping part 7, the valve core 72 is controlled to slide to a second working position to form a closed space, and a process gas is delivered from the inlet port 201 into the chamber body 1 to start the process reaction. During or after the process reaction, the valve core 72 is controlled to slide from the second working position to the first working position, so that the gas in the chamber body 1 is pumped by the pumping part 7. When pumped out, the process gas forms a uniform gas flow field in the first annulus 73, the second annulus 74, and the pumping region 5, and will uniformly flow through the pumping region 5, the first annulus 73, and the second annulus 74 in sequence from different directions of 360 degrees simultaneously, so that the gas in a space around the wafer stage 4 can be pumped into the pumping port 301 through the uniform gas flow field, thereby ensuring the uniformity in the wafer etching process results.

It will be appreciated that in the description of the specification, orientational or positional relationships referred by terms like “center”, “longitudinal”, “lateral”, “length”, “width”, “thickness”, “upper”, “lower”, “front”, “back”, “left”, “right”, “vertical”, “horizontal”, “top”, “bottom”, “inside”, “outside”, “clockwise”, “counter clockwise”, “axial”, “radial”, “circumferential” and the like are based on the orientational or positional relationship shown in the drawings, and are merely for an illustrative and simplified description of the present disclosure instead of indicting or implying that the device or element referred to must have a specific orientation, must be configured or operated at a specific orientation, and thus cannot be interpreted as limitations to the present disclosure.

Furthermore, the terms “first”, “second”, and the like are used for descriptive purposes only and are not to be construed as indicating or implying relative importance or to implicitly indicate a number of the indicated technical features. Therefore, a feature defined by “first” or “second” may include one or more of the indicated features either explicitly or implicitly. In the description of the present disclosure, “a plurality” means two or more unless explicitly defined otherwise.

In the present disclosure, unless otherwise explicitly stated or limited, the terms “mounted”, “connected”, “coupled”, “secured”, and the like are to be construed broadly, e.g., as meaning fixedly connected, detachably connected, or integral with; or mechanically connected or electrically connected, or communicated with; or directly connected, indirectly connected via an intermedium, or two elements in internal communication or interaction. Those ordinary skilled in the art may understand the specific meanings of the above terms in the present disclosure according to the specific context.

In the present disclosure, unless expressly stated or limited otherwise, a first feature “on” or “under” a second feature may include the first and second features in direct contact, or may include the case where the first feature and the second feature are not in direct contact, but in contact via an intermediate feature therebetween. Also, the first feature “on”, “above” or “over” the second feature may include the first feature being directly above and obliquely above the second feature, or simply indicate that the first feature is at a higher level than the second feature. The first feature “below”, “under” or “beneath” the second feature may include the first feature being directly below or obliquely below the second feature, or simply indicate that the first feature is at a lower level than the second feature.

The above disclosure provides many different implementations, or examples, for implementing different structures of the present disclosure. To simplify the disclosure of the present disclosure, components and setting in specific examples are described above. Apparently, these are merely examples and are not intended to limit the present disclosure. Moreover, the present disclosure may include repeated reference numerals and/or reference letters in various examples for purposes of simplicity and clarity, which do not in themselves dictate a relationship between the various implementations and/or settings discussed.

The above specific implementations should not be construed as limiting the scope of the present disclosure. It should be understood by those skilled in the art that various modifications, combinations, sub-combinations and substitutions may be made, depending on the design requirements and other factors. Any amendments, equivalent substitutions, improvements, or the like within the spirit and principle of the present disclosure shall be included in the protection scope of the present disclosure.

1. A reaction chamber applied to a wafer etching device, comprising:
a chamber body comprising a top plate and a bottom plate disposed oppositely in a vertical direction, wherein the top plate is provided with an inlet port, the bottom plate is provided with a pumping port a wafer stage is provided between the inlet port and the pumping port and a pumping region is formed between an inner wall of the chamber body and the wafer stage
a first support part disposed between the inner wall of the chamber body and the wafer stage; and
a pumping part comprising a valve plate and a valve core wherein the valve plate is disposed inside the chamber body and connected to a first end of the valve core, a second end of the valve core is liftably inserted into the pumping port, and when the valve core is in a first working position, a first annulus is formed between the valve plate and the bottom plate and a second annulus is formed between the valve core and the pumping port;
wherein the first annulus, the second annulus and the pumping region are disposed coaxially.

2. The reaction chamber according to claim 1, wherein the pumping part further comprises a valve body disposed outside the chamber body and connected to the pumping port the second end of the valve core is liftably inserted into the pumping port and the valve body and the second annulus is formed between the valve core and the pumping port, and between the valve core and an inner wall of the valve body.

3. The reaction chamber according to claim 2, wherein the pumping part further comprises a pump body connected to the pumping port via the valve body.

4. The reaction chamber according to claim 1, wherein when the valve core is in a second working position, the valve plate contacts the bottom plate to close the pumping port.

5. The reaction chamber according to claim 4, further comprising:
a seal ring provided at the pumping port wherein when the valve core is in the second working position, the valve plate contacts the seal ring.

6. The reaction chamber according to claim 1, wherein a plurality of first support parts are provided and uniformly arranged along a circumferential direction of the wafer stage.

7. The reaction chamber according to claim 8, wherein a cross section of each first support part in a horizontal direction has a width being one tenth to one half of a radius of the wafer stage.

8. The reaction chamber according to claim 1, wherein the first support part has a tubular structure, a first port of the first support part is communicated with the chamber body, and a second port of the first support part is communicated with the wafer stage.

9. The reaction chamber according to claim 1, further comprising:
a first jacking mechanism comprising a first tubular body and a rod body, wherein the first tubular body is connected to the bottom plate one end of the rod body is slidably inserted into the first tubular body the other end of the rod body extends into the chamber body to be connected to the valve plate and the rod body is configured to drive the valve plate and the valve core to make lifting movement.

10. The reaction chamber according to claim 9, comprising a plurality of first jacking mechanisms uniformly arranged along a circumferential direction of the valve plate.

11. A wafer etching device comprising:
a reaction chamber, comprising:
a chamber body comprising a top plate and a bottom plate disposed oppositely in a vertical direction, wherein the top plate is provided with an inlet port, the bottom plate is provided with a pumping port, a wafer stage is provided between the inlet port and the pumping port, and a pumping region is formed between an inner wall of the chamber body and the wafer stage;
a first support part disposed between the inner wall of the chamber body and the wafer stage; and
a pumping part comprising a valve plate and a valve core, wherein the valve plate is disposed inside the chamber body and connected to a first end of the valve core, a second end of the valve core is liftably inserted into the pumping port, and when the valve core is in a first working position, a first annulus is formed between the valve plate and the bottom plate; and a second annulus is formed between the valve core and the pumping port;
wherein the first annulus, the second annulus, and the pumping region are disposed coaxially.

12. The reaction chamber according to claim 2, wherein when the valve core is in a second working position, the valve plate contacts the bottom plate to close the pumping port (301).

13. The reaction chamber according to claim 3, wherein when the valve core is in a second working position, the valve plate contacts the bottom plate to close the pumping port.

14. The reaction chamber according to claim 2, wherein a plurality of first support parts are provided and uniformly arranged along a circumferential direction of the wafer stage.

15. The reaction chamber according to claim 3, wherein a plurality of first support parts are provided and uniformly arranged along a circumferential direction of the wafer stage.

16. The reaction chamber according to claim 2, wherein the first support part has a tubular structure, a first port of the first support part is communicated with the chamber body, and a second port of the first support part is communicated with the wafer stage.

17. The reaction chamber according to claim 3, wherein the first support part has a tubular structure, a first port of the first support part is communicated with the chamber body, and a second port of the first support part is communicated with the wafer stage.

18. The reaction chamber according to claim 2, further comprising:
a first jacking mechanism comprising a first tubular body and a rod body, wherein the first tubular body is connected to the bottom plate, one end of the rod body is slidably inserted into the first tubular body, the other end of the rod body extends into the chamber body to be connected to the valve plate, and the rod body is configured to drive the valve plate and the valve core to make lifting movement.

19. The reaction chamber according to claim 3, further comprising:
a first jacking mechanism comprising a first tubular body and a rod body, wherein the first tubular body is connected to the bottom plate, one end of the rod body is slidably inserted into the first tubular body, the other end of the rod body extends into the chamber body to be connected to the valve plate, and the rod body is configured to drive the valve plate and the valve core to make lifting movement.
